(19) United States
(12) Patent Application Publication
(10) Pub. No.: US 2013/0049801 A1
(43) Pub. Date: Feb. 28, 2013

(54) FPGA configuration equipment and configuration method

(71) Applicant: Yinming Sun, Chengdu (CN)

(72) Inventor: Yinming Sun, Chengdu (CN)

(73) Assignee: IPGoal Microelectronics (Sichuan) Co., Ltd.

(21) Appl. No.: 13/490,291

(22) Filed: Jun. 6, 2012

(30) Foreign Application Priority Data
Aug. 30, 2011 (CN) 201110252074.0

(51) Int. Cl. H03K 19/173

(52) U.S. Cl. 326/38

(57) ABSTRACT

An FPGA (Field-Programmable Gate Array) configuration equipment for sending configuration files stored in a smart card to an FPGA, includes a microprocessor, an FPGA interface connected with the microprocessor, a smart card interface connected with the microprocessor for inserting the smart card thereinto, and a switch selection module connected with the microprocessor for reading inputted numbers. The data are transmitted between the microprocessor and the smart card by the smart card interface. The configuration files of the corresponding numbers in the smart card are selected by the microprocessor according to the numbers read by the switch selection module, and the selected configuration files are sent to the FPGA by the FPGA interface. The present invention saves the cost and improves the efficiency of the development and validation.

### BACKGROUND OF THE PRESENT INVENTION

1. Field of Invention

The present invention relates to a configuration equipment and configuration method, and more particularly to an FPGA (Field-Programmable Gate Array) configuration equipment and configuration method.

2. Description of Related Arts

FPGA (Field-Programmable Gate Array) appears as a semi-custom circuit in the application-specific integrated circuit field. It overcomes not only the shortcomings of the custom circuit but also the disadvantage that the number of the gate circuits of the existing programmable device is limited, thereby it is widely used in the development and validation process of the electronic system. While working, it is needed for FPGA to configure the connection relations of the internal circuits. Generally, the data in a data memory which can store the configuration files of FPGA, namely, EPROM (Erasable Programmable Read-Only Memory), are read into an on-chip programmable RAM (Random Access Memory). After the configuration, FPGA goes into the working state. After power off, FPGA recovers to the blank chip and the connection relations of the internal circuits disappear, thereby FPGA cannot work normally until the re-configuration is made while power on every time. The configuration files are generated by the FPGA development software. Generally, the special configuration chip is used to configure FPGA. A configuration chip can accommodate a configuration file at the same time, and it is not only expensive and capacity-limited but also slow at the speed of update data, thereby causing a lot of inconvenience to the practical applications.

In addition, during the actual development and validation process, the configuration of FPGA is needed to be updated for many times, or the configuration files are needed to be frequently changed for contrasting the differences among a plurality of configuration files in the actual functions. Accordingly, the configuration chips are needed to be continuously burned based on the special configuration chips, which is slow and also easy to confuse different functions of the configuration files, thereby affecting the development and validation efficiency.

### SUMMARY OF THE PRESENT INVENTION

An object of the present invention is to provide an FPGA configuration equipment and configuration method, which is capable of storing a plurality of configuration files, and conveniently changing various configuration files.

Accordingly, in order to accomplish the above object, the present invention provides an FPGA (Field-Programmable Gate Array) configuration equipment for sending configuration files stored in a smart card to an FPGA, comprising a microprocessor, an FPGA interface connected with the microprocessor, a smart card interface connected with the microprocessor for inserting the smart card thereinto, and a switch selection module connected with the microprocessor for reading inputted numbers, wherein data are transmitted between the microprocessor and the smart card by the smart card interface, the configuration files of the corresponding numbers in the smart card are selected by the microprocessor according to the numbers read by the switch selection module, and the selected configuration files are sent to the FPGA by the FPGA interface.

Also, the present invention provides an FPGA (Field-Programmable Gate Array) configuration method for sending configuration files stored in a smart card to an FPGA, comprising the steps of:

(1) detecting whether a smart card is inserted into a smart card interface by a microprocessor, wherein if the smart card is inserted into the smart card interface, then go into a next step, and if the smart card is not inserted into the smart card interface, then directly exit a configuration;

(2) judging whether the smart card works normally by the microprocessor, wherein if the smart card works normally, then go into a next step, and if not, then directly exit the configuration;

(3) scanning the smart card by the microprocessor, counting the number of configuration files in the smart card, and judging whether the number of the configuration files stored in the smart card is zero, wherein if the number is zero, then directly exit the configuration, and if the number is not zero, then go into a next step;

(4) reading inputted numbers via a switch selection module by the microprocessor;

(5) selecting corresponding configuration files in the smart card according to the numbers read by the microprocessor; and

(6) sending the selected configuration files to the FPGA via an FPGA interface by the microprocessor.

Compared with the prior art, the FPGA configuration equipment and configuration method of the present invention can store a plurality of configuration files and conveniently change various configuration files, thereby saving the cost, improving the efficiency of the development and validation, and solving the problems of the FPGA special configuration chip in the development and validation.

These and other objectives, features, and advantages of the present invention will become apparent from the following detailed description, the accompanying drawings, and the appended claims.

### BRIEF DESCRIPTION OF THE DRAWINGS

FIG. 1 is a system frame diagram of an FPGA configuration equipment according to a preferred embodiment of the present invention.

FIG. 2 is a flow chart of an FPGA configuration method according to a preferred embodiment of the present invention.

### DETAILED DESCRIPTION OF THE PREFERRED EMBODIMENT

The present invention is further explained in detail with the accompanying drawings.

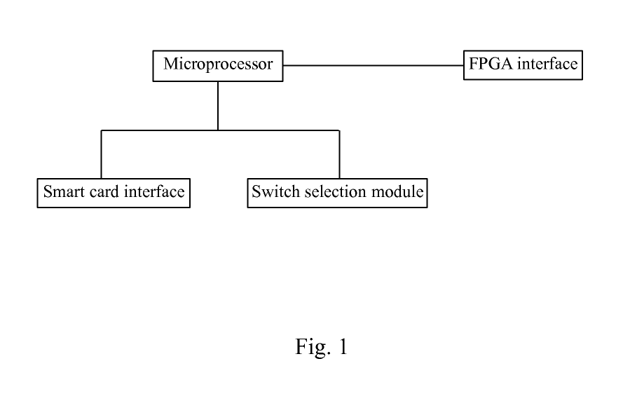

Referring to FIG. 1 of the drawings, an FPGA (Field-Programmable Gate Array) configuration equipment according to a preferred embodiment of the present invention is illustrated, which comprises a microprocessor, an FPGA interface connected with the microprocessor; a smart card interface connected with the microprocessor, and a switch selection module connected with the microprocessor. In the preferred embodiment of the present invention, the smart card interface is a SD card (Secure Digital Memory Card) interface.

The SD card interface is adapted for inserting a SD card thereinto. The data are transmitted between the microprocessor and the SD card via the SD card interface by the SPI (Serial Peripheral Interface) bus system mode. The SD card interface is compatible with all series of SD cards, and compatible with the standard SD card reader, that is to say, the configuration files can be copied by the standard SD card reader. The switch selection module is adapted for reading the numbers inputted by users. The microprocessor can select the configuration file of the corresponding number in the SD card according to the number read by the switch selection module. The switch selection module uses the code switch design, and can input number 1-255 by one-to-eight bit input methods, that is to say, the microprocessor can select 1-255 configuration files in the SD card. The FPGA interface is adapted for transferring the configuration files to the random access memory within the FPGA. The FPGA interface adopts the standard AS (Active Serial) configuration method. The configuration files are transferred to the random access memory within the FPGA via the FPGA interface controlled by the microprocessor cooperated with the timing of FPGA. The timing produced by the microprocessor is flexible and able to compatible with all series of Altera FPGA (an FPGA brand). The microprocessor is adapted for testing the SD card and searching, reading and transferring the configuration files.

A configuration process of the FPGA configuration equipment according to a preferred embodiment of the present invention is described as follows: firstly, store a plurality of configuration files in a SD card, and then insert the SD card into a SD card interface of the FPGA configuration equipment and begin to configure FPGA, and then the microprocessor will detect whether the SD card is inserted into the SD card interface by a SPI bus system model, wherein if no SD card is detected, then exit the configuration; if the SD card is detected, then further judge whether the SD card works normally, wherein if not, then exit the configuration, if the SD card works normally, the microprocessor will scan the SD card according to an FAT (Windows file system standard) format and count the number of the configuration files in the SD card, wherein if the number of the configuration files is zero, then exit the configuration, if the number of the configuration files is not zero, then the microprocessor reads the number by the switch selection module, and selects the configuration file of the corresponding number in the SD card, and then a timing is produced by the microprocessor according to the requirement of the FPGA and the selected configuration file is transferred to FPGA step by step via the FPGA interface, thereby completing the configuration of FPGA.

A plurality of configuration files can be stored and different configuration files can be conveniently changed by the FPGA configuration equipment mentioned above, thereby saving the cost, improving the efficiency of the development and validation, and solving the problems of the FPGA special configuration chip in the development and validation.

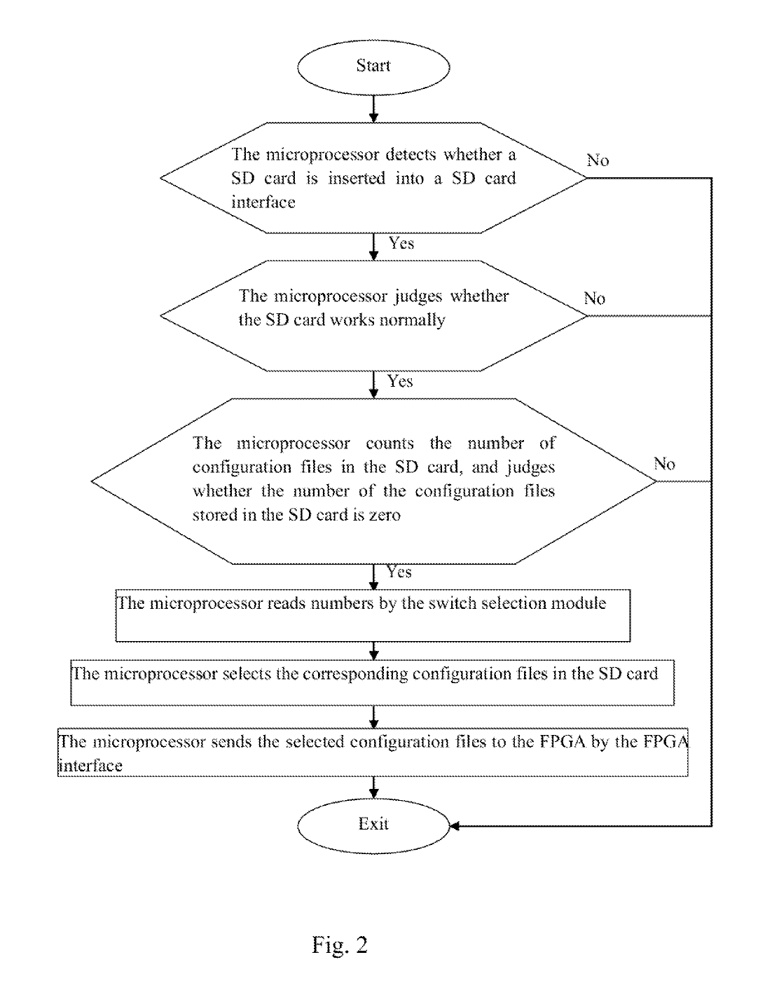

Referring to FIG. 2 of the drawings, an FPGA configuration method according to a preferred embodiment of the present invention is illustrated, which comprises the steps as follows.

(1) Store a plurality of configuration files in a SD card, insert the SD card into a SD card interface and begin to configure FPGA.

(2) A microprocessor detects whether the SD card is inserted into the SD card interface by a SPI bus system model, wherein if the SD card is inserted into the SD card interface, then go into a next step (3), and if the SD card is not inserted into the SD card interface, then directly exit the configuration.

(3) The microprocessor judges whether the SD card works normally, wherein if the SD card works normally, then go into a next step (4), and if not, then directly exit the configuration.

(4) The microprocessor scans the SD card according to an FAT format, counts the number of configuration files in the SD card, and judges whether the number of the configuration file stored in the SD card is zero, wherein if the number is zero, namely, no configuration files in the SD card, then directly exit the configuration, and if the number is not zero, namely, there are configuration files in the SD card, then go into a next step (5).

(5) The microprocessor reads numbers inputted by users by a switch selection module.

(6) The microprocessor selects corresponding configuration files in the SD card according to the read numbers.

(7) Timings are produced by the microprocessor according to requirements of the FPGA and the selected configuration files are sent to FPGA step by step by the FPGA interface, thereby completing a configuration of FPGA.

(8) Exit the configuration.

While developing a data acquisition system and using FPGA to make the functional verification, the configuration files in the FPGA are needed to be continuously modified and the verification results of several tests are needed to be compared so as to improve the stability of the system. Furthermore, it is needed for the special FPGA configuration chip to be burned by the computer for many times. Therefore, the efficiency is low and it is inconvenient to operate. After using this invention, the configuration files can be copied into the SD card one by one, and then the SD card is inserted into the configuration equipment to use, thereby improving the efficiency.

In the development of a USB system, while using FPGA to make the logically functional verification, many situations are needed to be tested and the problems which occur at every situation can be timely backtracked for keeping the integrity of the test. It is needed for the special FPGA configuration chip to be burned by the computer for many times, thus the efficiency is low and the operation is inconvenient. After using this invention, various configuration files can be copied into the SD card one by one, and then the SD card is inserted into the configuration equipment for conveniently selecting various configuration files, thereby improving the efficiency.

The FPGA configuration equipment and the configuration method of the present invention can store a plurality of configuration files and change different configuration files easily, thereby saving the cost, improving the efficiency of the development and validation and solving the problems of the FPGA special configuration chip in the development and validation.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. An FPGA (Field-Programmable Gate Array) configuration equipment, for sending configuration files stored in a smart card to an FPGA, comprising:
a microprocessor, an FPGA interface connected with the microprocessor, a smart card interface connected with the microprocessor for inserting the smart card thereinto, and a switch selection module connected with the microprocessor for reading inputted numbers, wherein data are transmitted between the microprocessor and the smart card by the smart card interface, the configuration files of the corresponding numbers in the smart card are selected by the microprocessor according to the numbers read by the switch selection module, and the selected configuration files are sent to the FPGA by the FPGA interface.

2. The FPGA configuration equipment, as recited in claim 1, wherein the smart card interface is a SD card (Secure Digital Memory Card) interface.

3. The FPGA configuration equipment, as recited in claim 1, wherein the data are transmitted between the microprocessor and the smart card via the smart card interface by a SPI (Serial Peripheral Interface) bus system mode.

4. The FPGA configuration equipment, as recited in claim 2, wherein the data are transmitted between the microprocessor and the smart card via the smart card interface by a SPI (Serial Peripheral Interface) bus system mode.

5. The FPGA configuration equipment, as recited in claim 1, wherein the switch selection module uses the code switch design and inputs numbers by one-to-eight bit input methods.

6. The FPGA configuration equipment, as recited in claim 2, wherein the switch selection module uses the code switch design and inputs numbers by one-to-eight bit input methods.

7. The FPGA configuration equipment, as recited in claim 3, wherein the switch selection module uses the code switch design and inputs numbers by one-to-eight bit input methods.

8. The FPGA configuration equipment, as recited in claim 4, wherein the switch selection module uses the code switch design and inputs numbers by one-to-eight bit input methods.

9. The FPGA configuration equipment, as recited in claim 5, wherein the FPGA interface adopts a standard AS (Active Serial) configuration method.

10. The FPGA configuration equipment, as recited in claim 6, wherein the FPGA interface adopts a standard AS (Active Serial) configuration method.

11. An FPGA (Field-Programmable Gate Array) configuration method, comprising the steps of:
(1) detecting whether a smart card is inserted into a smart card interface by a microprocessor, wherein if the smart card is inserted into the smart card interface, then go into a next step, and if the smart card is not inserted into the smart card interface, then directly exit a configuration;
(2) judging whether the smart card works normally by the microprocessor, wherein if the smart card works normally, then go into a next step, and if not, then directly exit the configuration;
(3) scanning the smart card by the microprocessor, counting the number of configuration files in the smart card, and judging whether the number of the configuration files stored in the smart card is zero, wherein if the number is zero, then directly exit the configuration, and if the number is not zero, then go into a next step;
(4) reading inputted numbers via a switch selection module by the microprocessor;
(5) selecting corresponding configuration files in the smart card according to the numbers read by the microprocessor; and
(6) sending the selected configuration files to the FPGA via an FPGA interface by the microprocessor.

12. The FPGA configuration method, as recited in claim 11, further comprising storing a plurality of configuration files in the smart card, inserting the smart card into the smart card interface and beginning the FPGA configuration before the step (1).

13. The FPGA configuration method, as recited in claim 11, wherein the microprocessor detects whether the smart card is inserted into the smart card interface by a SPI (Serial Peripheral Interface) bus system mode.

14. The FPGA configuration method, as recited in claim 12, wherein the microprocessor detects whether the smart card is inserted into the smart card interface by a SPI (Serial Peripheral Interface) bus system mode.

15. The FPGA configuration method, as recited in claim 11, wherein the microprocessor scans the smart card according to an FAT (Windows file system standard) format and count the number of the configuration files in the smart card.

16. The FPGA configuration method, as recited in claim 12, wherein the microprocessor scans the smart card according to an FAT (Windows file system standard) format and count the number of the configuration files in the smart card.

17. The FPGA configuration method, as recited in claim 13, wherein the microprocessor scans the smart card according to an FAT (Windows file system standard) format and count the number of the configuration files in the smart card.

18. The FPGA configuration method, as recited in claim 14, wherein the microprocessor scans the smart card according to an FAT (Windows file system standard) format and count the number of the configuration files in the smart card.

19. The FPGA configuration method, as recited in claim 11, wherein the smart card interface is a SD card (Secure Digital Memory Card) interface.

20. The FPGA configuration method, as recited in claim 18, wherein the smart card interface is a SD card (Secure Digital Memory Card) interface.
